(19) United States
(12) Patent Application Publication
(10) Pub. No.: US 2007/0284080 A1
(43) Pub. Date: Dec. 13, 2007

(54) HEAT DISSIPATION DEVICE

(75) Inventor: Zheng-Heng Sun, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,730

(22) Filed: Sep. 15, 2006

(30) Foreign Application Priority Data
Jun. 9, 2006 (CN) 200610061067.1

(51) Int. Cl. H05K 7/20

(52) U.S. Cl. 165/80.3; 361/704

(57) ABSTRACT

A heat dissipation device includes a base, and a plurality of parallel fins extending up from the base. Every two adjacent fins are spaced from each other for forming a passage to allow airflow therethrough. Together, the passages form an air inlet at one side of the heat dissipation device and an air outlet at an opposite side of the heat dissipation device. Each fin has an air conductive portion located at a side thereof nearby the air inlet. Each air conductive portion gradually tapers in a direction away from the device.

### 1. FIELD OF THE INVENTION

The present invention relates to heat dissipation devices, and particularly to a heat dissipation device structured and arranged for heat dissipation of electrical components.

### 2. DESCRIPTION OF RELATED ART

Advances in microelectronics technology have brought us electronic devices, which process signals and data at unprecedented speeds. During operation of many contemporary electronic devices, such as CPUs (Central Processing Units), large amounts of heat are produced. The heat must be efficiently removed, to prevent the system from becoming unstable or being damaged. Heat dissipation devices, such as heat sinks, are frequently used to dissipate heat from these electronic devices.

Referring to FIG. 4, a conventional heat sink 10 which is made of aluminum or copper materials includes a base 12, and a plurality of combined fins 14 extending up from the base 12. The base 12 is a tablet shaped metal block with flat top and bottom surfaces. The heat sink 10 is attached to an electrical device (such as a CPU) 18 of a motherboard 16 for heat dissipation. The bottom surface of the base 12 contacts the electric device 18. Each of the fins 14 has a certain width for transferring heat from the electric device 18. Every two adjacent fins 14 are spaced from each other for forming a passage to dissipate heat.

A fan (not shown) is set, to assist in heat dissipation, at a certain distance from the heat sink 10. Airflow from the fan passes through the heat sink 10. The airflow produces vortexes when passing across a side of each fin 14 because of the width of the fins 14. Thus, resistance to the airflow increases when air flows through the heat sink 10, thereby reducing heat dissipation of the heat sink 10.

What is desired, therefore, is a heat dissipation device which provides high efficiency of heat dissipation.

### SUMMARY OF THE INVENTION

In one preferred embodiment, a heat dissipation device includes a base, and a plurality of parallel fins extending up from the base. Every two adjacent fins are spaced from each other for forming a passage to allow airflow therethrough. Together, the passages form an air inlet at one side of the heat dissipation device and an air outlet at an opposite side of the heat dissipation device. Each fin has an air conductive portion located at a side thereof nearby the air inlet. Each air conductive portion gradually tapers in a direction away from the device.

Other advantages and novel features will become more apparent from the following detailed description when taken in conjunction with the accompanying drawings, in which:

### BRIEF DESCRIPTION OF THE DRAWINGS

FIG. 1 is an exploded, isometric view of a heat dissipation device in accordance with a first preferred embodiment of the present invention;

FIG. 2 is an assembled view of a motherboard and the heat dissipation device of FIG. 1;

FIG. 3 is an assembled view of a motherboard and a heat dissipation device in accordance with a second preferred embodiment of the present invention; and

FIG. 4 is a front view of a conventional heat sink, together with a motherboard.

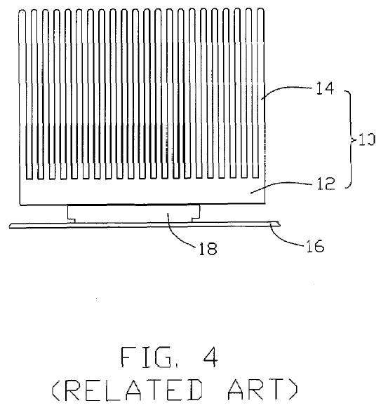

### DETAILED DESCRIPTION OF THE INVENTION

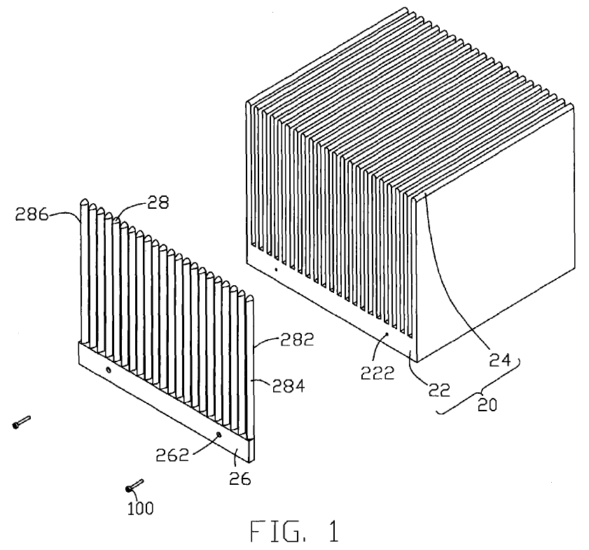

Referring to FIG. 1, a heat dissipation device in accordance with a first preferred embodiment of the present invention is shown. The heat dissipation device includes a heat sink 20, and an air-guiding element. The heat sink 20 includes a heat-conductive base 22, and a plurality of parallel fins 24 extending up from the base 22. All fins 24 have the same width. Every two adjacent fins 14 are spaced from each other for forming a passage to allow airflow therethrough for dissipating heat. Together, the passages form an air inlet at one side of the heat sink 20 and an air outlet at an opposite side of the heat sink 20.

The air-guiding element includes a tablet shaped fixing portion 26, and a plurality of prism shaped air conductive portions 28 extending up from a top of the fixing portion 26. A length and a height of the fixing portion 26 are respectively equal to those of a corresponding sidewall of the base 22 nearby the air inlet of the passage. A thickness of the fixing portion 26 is designed according to actual needs. A cross section of each air conductive portion 28 is generally triangular shaped. Each air conductive portion 28 includes a vertical plane 282 perpendicular to the top of the fixing portion 26 and facing the heat sink 20, and two conducting planes 284, 286 slanting from opposite borders of the vertical plane 282 in a direction away from the heat sink 20 to converge at an intersecting line. A width and a height of the vertical plane 282 of each air conductive portion 28 are respectively equal to those of a corresponding fin 24. According to actual needs, the conducting planes 284, 286 may also be smooth cambers or flat slanting plane.

Two threaded holes 222 are defined in the sidewall of the base 22 nearby the air inlet. Two through holes 262 are defined in the fixing portion 26, corresponding to the threaded holes 222 of the base 22.

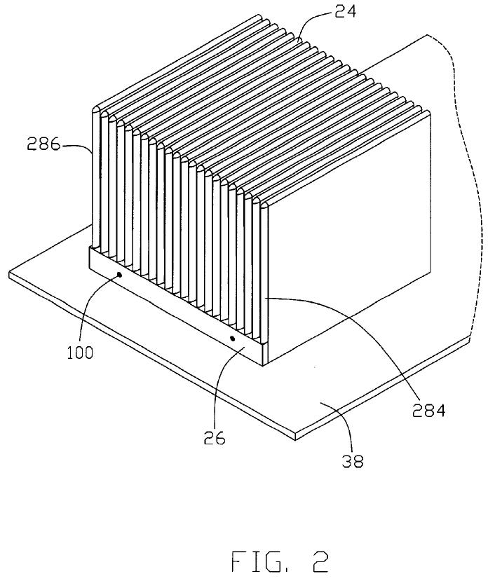

Referring also to FIG. 2, in assembly, each vertical plane 282 of each air conductive portion 28 is respectively abutted against the sidewall of a corresponding fin 24 nearby the air inlet. Two screws 100 are respectively inserted through the through holes 262 of the fixing portion 26 to be respectively engaged in the threaded holes 222 of the base 22, so that the air-guiding element is mounted to the sidewall of the heat sink 20 nearby the air inlet. The air-guiding element may also be attached to the heat sink 20 by other known means, such as bonding.

In use, the heat dissipation device is attached to an electronic component (not shown), such as a CPU, of a motherboard 38 for heat dissipation. A planar part of a bottom surface of the base 22 is attached to a top surface of the electronic component. A fan (not shown) is set, to assist in heat dissipation, at a certain distance from the heat dissipation device. Airflow from the fan enters the air inlet of the heat dissipation device easily because of a tapered contour of the air conductive portions 28.

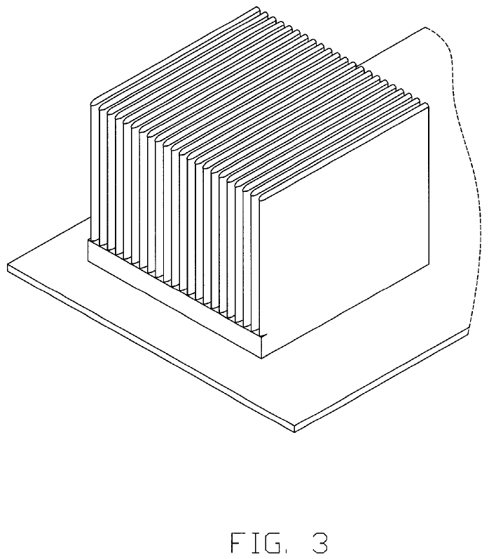

Referring also to FIG. 3, a heat dissipation device in accordance with a second preferred embodiment is shown. A difference between the second preferred embodiment and the first preferred embodiment of the invention is that in the second preferred embodiment the air conductive portion and the heat sink are integrally formed.

It is to be understood, however, that even though numerous characteristics and advantages of the preferred embodiments have been set forth in the foregoing description, together with details of the structures and functions of the embodiments, the disclosure is illustrative only, and changes may be made in detail, especially in matters of shape, size, equivalent material and arrangement of parts within the principles of the invention to the full extent indicated by the broad general meaning of the terms in which the appended claims are expressed.

What is claimed is:

1. A heat dissipation device comprising:
a heat sink comprising a heat-conductive base, and a plurality of parallel fins extending up from a top surface of the base; every two adjacent fins spaced from each other for forming a passage to allow airflow to flow therethrough, together, the passages forming an air inlet at one side of the heat sink; and
a plurality of air conductive portions arranged at the inlet and gradually tapering in a direction away from the heat sink.

2. The heat dissipation device as claimed in claim 1, wherein each of the air conductive portions comprises two conducting planes.

3. The heat dissipation device as claimed in claim 2, wherein the two conducting planes extend from opposite borders of a sidewall of each fin nearby the air inlet in a direction away from the corresponding fin to converge at an intersecting line.

4. The heat dissipation device as claimed in claim 3, wherein the two conducting planes are slanting planes.

5. The heat dissipation device as claimed in claim 3, wherein the two conducting planes are smooth cambers.

6. The heat dissipation device as claimed in claim 1, wherein the air conductive portions are formed in an air-guiding element detachably mounted to the side of the heat sink.

7. The heat dissipation device as claimed in claim 6, wherein the air-guiding element comprises a fixing portion, the air conductive portions extend up from a top of the fixing portion, and each of the air conductive portions comprises a vertical plane, and two conducting planes extending from opposite borders of the vertical plane in a direction away from the heat sink to converge at an intersecting line.

8. The heat dissipation device as claimed in claim 7, wherein a width and a height of each of the vertical planes are respectively equal to those of a corresponding fin of the heat sink.

9. The heat dissipation device as claimed in claim 7, wherein the two conducting planes are slanting planes.

10. The heat dissipation device as claimed in claim 7, wherein the two conducting planes are smooth cambers.

11. The heat dissipation device as claimed in claim 6, wherein the air conductive portions are integrally formed with the heat sink.

12. A heat dissipation device comprising:
a heat sink comprising a plurality of fins, every two adjacent fins spaced from each other to form a passage for allowing airflow to flow therethrough, the passage forming an inlet at one side of the heat sink; and
a plurality of air conductive portions arranged at the inlet and gradually tapering in a direction away from the heat sink.

13. The heat dissipation device as claimed in claim 12, wherein each of the air conductive portions comprises two conducting planes extending from opposite sides of a distal end of each fin nearby the air inlet in a direction away from the corresponding fin.

14. The heat dissipation device as claimed in claim 13, wherein the two conducting planes converge at an intersecting line.

15. The heat dissipation device as claimed in claim 14, wherein the two conducting planes are flat slanting planes.

16. The heat dissipation device as claimed in claim 13, wherein the two conducting planes are smooth cambers.

17. The heat dissipation device as claimed in claim 13, wherein the air conductive portions are integrally formed with the heat sink.

18. The heat dissipation device as claimed in claim 13, wherein the air conductive portions are detachably mounted to the heat sink.
